(19) United States
(12) Patent Application Publication
(10) Pub. No.: US 2025/0266370 A1
(43) Pub. Date: Aug. 21, 2025

(54) SEMICONDUCTOR PACKAGING DEVICE AND METHOD OF MANUFACTURING THE SEMICONDUCTOR PACKAGING DEVICE

(71) Applicant: SAMSUNG ELECTRONICS CO., LTD., Suwon-si (KR)

(72) Inventor: Hyunsoo CHUNG, Suwon-si (KR)

(21) Appl. No.: 19/045,314

(22) Filed: Feb. 4, 2025

(30) Foreign Application Priority Data
Feb. 16, 2024 (KR) 10-2024-0022190

(51) Int. Cl. H01L 23/552; H01L 23/00; H01L 23/31; H01L 25/00; H01L 25/03

(52) U.S. Cl. CPC H01L 23/552; H01L 23/3135; H01L 24/24; H01L 24/25; H01L 25/03; H01L 25/50; H01L 24/16; H01L 24/32; H01L 24/73; H01L 2224/16227; H01L 2224/24146; H01L 2224/24226; H01L 2224/2518; H01L 2224/32225; H01L 2224/73204

(57) ABSTRACT

A semiconductor packaging device includes a lower redistribution wiring layer, a lower sealing member on the lower redistribution wiring layer that contains a first chiplet die and has a plurality of through vias therein, and an upper redistribution wiring layer on the lower sealing member. The upper redistribution wiring layer includes first bonding pads in a first region and second bonding pads in a second region, and a second chiplet die in the first region. An upper sealing member is on the lower redistribution wiring layer and covers the lower sealing member, the upper redistribution wiring layer and the second chiplet die. Conductive ground structures extend from the upper surface of the upper sealing member to the second bonding pads of the upper redistribution wiring layer, and an electromagnetic shielding layer is on the upper surface of the upper sealing member and electrically connected to the conductive ground structures.

### PRIORITY STATEMENT

This application claims priority under 35 U.S.C. § 119 to Korean Patent Application No. 10-2024-0022190, filed on Feb. 16, 2024 in the Korean Intellectual Property Office (KIPO), the disclosure of which is herein incorporated by reference in its entirety.

### BACKGROUND

### 1. Field

Example embodiments relate to a semiconductor packaging device and a method of manufacturing the semiconductor packaging device. More particularly, example embodiments relate to a semiconductor packaging device including a plurality of stacked semiconductor chips and a method of manufacturing the semiconductor packaging device.

### 2. Description of the Related Art

In manufacturing a 3D IC package, a lower chip may be stacked on a wafer including an upper chip formed therein by a chip-on-wafer bonding process. In this case, there may be a problem that package manufacturing costs increase when the yield of the wafer is reduced. Meanwhile, after forming a fan-out wafer-level package including a lower chip, an upper chip may be stacked on the fan-out wafer-level package. In this case, the fan-out wafer level package may have the disadvantage that warpage occurs due to a relative large area of a molding layer, and a redistribution wiring layer between the upper chip and the lower chip is exposed to the outside, making it vulnerable to moisture absorption and impact. Additionally, there may be a problem in that it is difficult to form an electromagnetic wave shielding layer to shield electromagnetic waves emitted from the upper chip on the fan-out wafer-level package.

### SUMMARY

Example embodiments provide a semiconductor package capable of preventing warpage and having improved bonding quality and an electromagnetic wave shielding function.

Example embodiments provide a method of manufacturing the semiconductor package.

According to example embodiments, a semiconductor packaging device includes a lower redistribution wiring layer; a lower die structure stacked on the lower redistribution wiring layer, and including a first semiconductor chip, a lower sealing member extending around the first semiconductor chip, a plurality of through vias penetrating the lower sealing member, and an upper redistribution wiring layer on the lower sealing member. The upper redistribution layer includes first bonding pads in a first region and second bonding pads in a second region that extends peripherally around the first region. A second semiconductor chip is on the lower die structure in the first region. An upper sealing member is on the lower redistribution wiring layer and covers the lower die structure and the second semiconductor chip. Conductive ground structures extend from an upper surface of the upper sealing member to the second bonding pads in the second region of the upper redistribution wiring layer. An electromagnetic shielding layer is on the upper surface of the upper sealing member and is electrically connected to the conductive ground structures.

According to example embodiments, a semiconductor packaging device includes a lower redistribution wiring layer, a lower sealing member on the lower redistribution wiring layer, wherein the lower sealing member contains a first chiplet die and includes a plurality of through vias therein. An upper redistribution wiring layer is on the lower sealing member and includes first bonding pads in a first region of the upper redistribution wiring layer and second bonding pads in a second region of the upper redistribution wiring layer that extends peripherally around the first region of the upper redistribution wiring layer. A second chiplet die is in the first region of the upper redistribution wiring layer, an upper sealing member is on the lower redistribution wiring layer and covers the lower sealing member, the upper redistribution wiring layer, and the second chiplet die. A plurality of conductive ground structures extend from an upper surface of the upper sealing member to the second bonding pads of the upper redistribution wiring layer, and an electromagnetic shielding layer is on the upper surface of the upper sealing member and electrically connected to the conductive ground structures.

According to example embodiments, a semiconductor packaging device includes a lower redistribution wiring layer, a first chiplet die on the lower redistribution wiring layer and having a first size, a lower sealing member extending around the first chiplet die and having a plurality of through vias therein. An upper redistribution wiring layer is on the first chiplet die and the lower sealing member and includes first bonding pads in a first region of the upper redistribution wiring layer and second bonding pads in a second region of the upper redistribution wiring layer that extends peripherally around the first region. A second chiplet die is in the first region of the upper redistribution wiring layer and has a second size greater than the first size. An upper sealing member is on the lower redistribution wiring layer and covers the lower sealing member, the upper redistribution wiring layer and the second chiplet die. A plurality of conductive ground structures extend from the upper surface of the upper sealing member to the second bonding pads in the second region of the upper redistribution wiring layer, and an electromagnetic shielding layer is on an upper surface of the upper sealing member and electrically connected to the conductive ground structures.

According to example embodiments, a semiconductor packaging device may include a lower redistribution wiring layer, a lower die structure stacked on the lower redistribution wiring layer, a second semiconductor chip stacked on the lower die structure, and an upper sealing member covering the lower die structure and the second semiconductor chip on the lower redistribution wiring layer. The lower die structure may include a lower sealing member that contains a first semiconductor chip and a plurality of through vias, and an upper redistribution wiring layer on the lower sealing member.

Since an elastic modulus of the lower sealing member is greater than an elastic modulus of the upper sealing member, impacts generated when bonding the second semiconductor chip on the lower die structure may be prevented or reduced. The upper sealing member may cover the upper redistribution wiring layer of the lower die structure so that the upper redistribution wiring layer is not exposed to an external environment, to thereby prevent moisture absorption and improve reliability.

Further, an electromagnetic shielding layer may cover an upper surface of the upper sealing member and may be grounded by conductive wires as conductive ground structures that extend in the upper sealing member. Thus, the electromagnetic shielding layer may effectively shield electromagnetic waves emitted from the second semiconductor chip.

### BRIEF DESCRIPTION OF THE DRAWINGS

Example embodiments will be more clearly understood from the following detailed description taken in conjunction with the accompanying drawings. FIGS. 1 to 26 represent non-limiting, example embodiments as described herein.

FIG. 1 is a cross-sectional view illustrating a semiconductor packaging device in accordance with example embodiments.

FIG. 2 is a plan view illustrating a lower die structure and an upper semiconductor chip sequentially stacked on a lower redistribution wiring layer in FIG. 1.

FIGS. 3 to 19 are views illustrating a method of manufacturing a semiconductor packaging device in accordance with example embodiments.

FIG. 20 is a cross-sectional view illustrating a semiconductor packaging device in accordance with example embodiments.

FIGS. 21 to 24 are cross-sectional views illustrating a method of manufacturing a semiconductor packaging device in accordance with example embodiments.

FIG. 25 is a cross-sectional view illustrating a semiconductor package in accordance with example embodiments.

FIG. 26 is a cross-sectional view illustrating a semiconductor package in accordance with example embodiments.

### DETAILED DESCRIPTION OF EXAMPLE EMBODIMENTS

Hereinafter, example embodiments will be explained in detail with reference to the accompanying drawings.

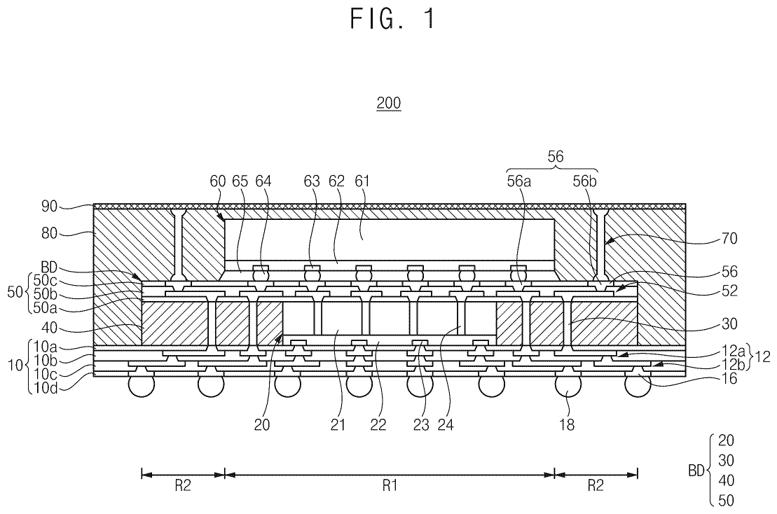

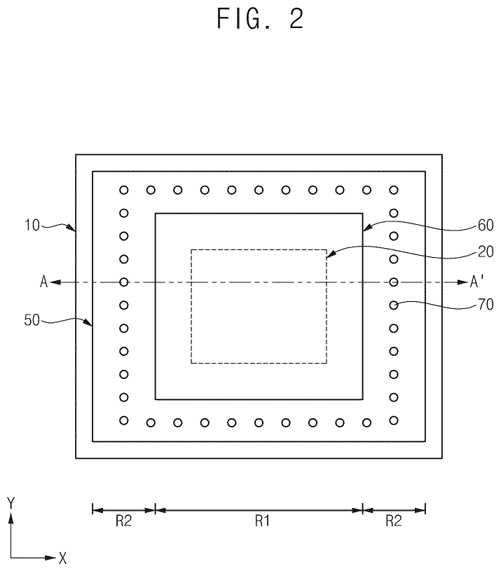

FIG. 1 is a cross-sectional view illustrating a semiconductor packaging device in accordance with example embodiments. FIG. 2 is a plan view illustrating a lower die structure and an upper semiconductor chip sequentially stacked on a lower redistribution wiring layer in FIG. 1.

Referring to FIGS. 1 and 2, a semiconductor packaging device 200 may include a lower redistribution wiring layer 10, a lower die structure BD, a second semiconductor chip 60, conductive wires 70 as conductive ground structures, and an electromagnetic shielding layer 90. The lower die structure BD may include a first semiconductor chip 20, a lower sealing member 40, and a plurality of through vias 30. Additionally, the semiconductor packaging device 200 may further include conductive bumps 18 provided on an outer surface of the lower redistribution wiring layer 10.

In example embodiments, the semiconductor packaging device 200 may be a multi-chip package (MCP) including different types of semiconductor chips. The semiconductor packaging device 200 may be a stack semiconductor chip as a chiplet package that includes a plurality of chiplet dies. The stack semiconductor chip may include the first semiconductor chip 20 as a first chiplet die and the second semiconductor chip 60 as a second chiplet die. The first semiconductor chip 20 and the second semiconductor chip 60 may be small structural units or IP block units that constitute a processor chip. The first semiconductor chip 20 and the second semiconductor chip 60 may be stacked on each other to provide a semiconductor chip with an independent function.

The semiconductor packaging device 200 may be provided as a logic chip including a logic circuit. The logic chip may be a controller that controls memory elements of a memory chip. For example, the logic chip may be an ASIC serving as a host such as a CPU, NPU, GPU, or SOC, or a processor chip such as an application processor (AP). The memory chip may include DRAM, SRAM, etc.

In this embodiment, the semiconductor packaging device as a multi-chip package is illustrated as including two stacked first and second chiplet dies 20 and 60. However, it is not limited thereto, and for example, the semiconductor packaging device may include 3 or 4 stacked semiconductor chips.

In example embodiments, the lower redistribution wiring layer 10 may include first, second, third and fourth lower insulating layers 10a, 10b, 10c, and 10d and lower redistribution wirings 12 in the first to fourth lower insulating layers. For example, the first to fourth lower insulating layers may include a photosensitive insulating layer such as a photo imageable dielectric (PID). The lower redistribution wirings may include aluminum (Al), copper (Cu), tin (Sn), nickel (Ni), gold (Au), platinum (Pt), or an alloy thereof.

The lower redistribution wirings 12 may include first lower redistribution wirings 12a formed on the first lower insulating layer 10a and second lower redistribution wirings 12b formed on the second lower insulating layer 10b and electrically connected to the first lower redistribution wirings 12a respectively. In this embodiment, the lower redistribution wiring layer is illustrated including two layers of lower redistribution wirings 12, but it is not limited thereto, and the lower redistribution wiring layer may have at least two layers of stacked lower redistribution wirings.

Lower bonding pads 16 may be formed on the third lower insulating layer 10c and may be electrically connected to the second lower redistribution wirings 12b. The lower bonding pads 16 may be exposed from a lower surface of the lower redistribution wiring layer 10. The lower bonding pad 16 may be a bump pad. The bump pad may include a solder pad and/or a pillar pad. For example, the lower bonding pad may include copper (Cu), aluminum (Al), tin (Sn), nickel (Ni), gold (Au), platinum (Pt), or an alloy thereof.

In example embodiments, the lower die structure BD may be stacked on the lower redistribution wiring layer 10. The lower die structure BD may include the first semiconductor chip 20, the lower sealing member 40 surrounding the first semiconductor chip 20, the plurality of through vias 30 penetrating the lower sealing member 40, and an upper redistribution wiring layer 50 disposed on the lower sealing member 40.

The first semiconductor chip 20 may be provided in the lower sealing member 40. When viewed in plan view, the first semiconductor chip 20 may be disposed within a fan-in region of the lower die structure BD, and the lower sealing member 40 may be disposed in a fan-out region of the lower die structure BD.

The first semiconductor chip 20 may include a first substrate 21, a first front insulating layer 22, first chip pads 23 and a plurality of through electrodes 24. The first front insulating layer 22 may be formed on a first surface 212 of the first substrate 21, that is, a front surface. The first front insulating layer 22 may include a plurality of insulating layers and wirings in the insulating layers. In addition, the first chip pads 23 may be provided in an outermost insulating layer of the first front insulating layer 22.

The through electrode 24 such as through silicon via (TSV) may extend from the first surface 212 of the first substrate 21 to a second surface, that is, a backside surface. The through electrode 24 may be electrically connected to the first chip pad 23 through the wirings. An upper end portion of the through electrode 24 may be exposed from (i.e., exposed at) the second surface of the first substrate 21.

The first semiconductor chip 20 may be arranged such that the front surface on which the first chip pads 23 are formed faces the lower redistribution wiring layer 10. The first chip pads 23 may be electrically connected to first lower redistribution wirings 12a of the lower redistribution wiring layer 10.

For example, the first substrate 21 may have a thickness within a range of about 30 μm to 150 μm. The through electrode 24 and the first chip pad 23 may include the same metal. For example, the metal may include copper (Cu), but may not be limited thereto.

In example embodiments, the lower sealing member 40 may be formed on the lower redistribution wiring layer 10 to expose an upper surface, that is, the second surface, of the first semiconductor chip 20. For example, the lower sealing member 40 may include an epoxy mold compound (EMC). The lower sealing member 40 may include fillers and epoxy resin as a binder for the fillers. The lower sealing member 40 may have a first elastic modulus. The first elastic modulus may be within a range of 20×10³ kgf/mm² to 27×10³ kgf/mm². The first elastic modulus may be determined according to a content ratio of the fillers.

The plurality of through vias 30 may extend in a vertical direction to penetrate the lower sealing member 40. Lower end portions of the through vias 30 may be exposed from (i.e., exposed at) a lower surface of the lower sealing member 40 and upper end portions of the through vias 30 may be exposed from (i.e., exposed at) an upper surface of the lower sealing member 40. The lower end portion of the through via 30 may be electrically connected to the first lower redistribution wiring 12a of the lower redistribution wiring layer 10.

In example embodiments, the upper redistribution wiring layer 50 may be disposed on the second surface of the first semiconductor chip 20 and the lower sealing member 40. The upper redistribution wiring layer 50 may include first, second and third upper insulating layers 50a, 50b, and 50c and upper redistribution wirings 52 in the first to third upper insulating layers 50a, 50b, and 50c. The upper redistribution wirings 52 may be electrically connected to the through electrodes 24 and the through vias 30, respectively. A side surface of the upper redistribution wiring layer 50 may be positioned on the same plane as a side surface of the lower sealing member 40 (i.e., the side surface of the upper redistribution wiring layer 50 may be co-planar with the a side surface of the lower sealing member 40).

The first upper insulating layer 50a may be provided on the upper surface of the first semiconductor chip 20 and the upper surface of the lower sealing member 40, and may have openings that expose the upper end portions of the through electrodes 24 and the upper end portions of the through vias 30. The upper redistribution wirings 52 may be formed on the first upper insulating layer 50a and may be electrically connected to the through electrodes 24 and the through vias 30 through the openings.

The second upper insulating layer 50b may be provided on the first upper insulating layer 50a and may have openings that expose the upper redistribution wirings 52. Upper bonding pads 56 may be formed on the upper redistribution wirings 52. The upper bonding pads 56 may be electrically connected to the upper redistribution wirings 52 through the openings formed in the second lower insulating layer 50b.

The third upper insulating layer 50c may be formed on the second upper insulating layer 50b and may expose portions of the upper bonding pads 56. The upper bonding pads 56 may be exposed from (i.e., exposed at) an upper surface of the upper redistribution wiring layer 50. For example, the upper bonding pads 56 may have a multilayer structure. The upper bonding pad 56 may include a bonding pad pattern and a plating pad pattern formed on the bonding pad pattern. The bonding pad pattern may include copper (Cu), and the plating pad pattern may include nickel (Ni), gold (Au), or titanium (Ti).

In example embodiments, the upper redistribution wiring layer 50 may include a first region R1 and a second region R2 surrounding the first region when viewed in plan view (i.e., the second region R2 extends peripherally around the first region R1). The upper bonding pads 56 may include first bonding pads 56a in the first region R1 and second bonding pads 56b in the second region R2. The first bonding pads 56a may be pads for connection with the second semiconductor chip 60, and the second bonding pads 56b may be pads for connection with the conductive ground structures.

The first bonding pad 56a may be electrically connected to the lower redistribution wiring 12 by the upper redistribution wiring 52, the through electrode 24 and the first chip pad 23, and the second bonding pad 56b may be electrically connected to the lower redistribution wiring 12 through the upper redistribution wiring 52 and the through via 30.

In example embodiments, the second semiconductor chip 60 may be disposed on the lower die structure BD. The second semiconductor chip 60 may be disposed in the first region R1 of the upper redistribution wiring layer 50.

The second semiconductor chip 60 may be mounted on the lower die structure BD using a flip chip bonding method. Second chip pads 63 of the second semiconductor chip 60 may be electrically connected to the first bonding pads 56a in the first region R1 of the upper redistribution wiring layer 50 by conductive bumps 64. The conductive bumps 64 may be formed on the second chip pads 63 of the upper semiconductor chip 60, respectively. For example, each of the conductive bumps 64 may include a pillar bump on the second chip pad 63 and a solder bump on the pillar bump. The pillar bump may include copper (Cu), aluminum (Al), tin (Sn), nickel (Ni), gold (Au), platinum (Pt), or an alloy thereof. The solder bump may include solder.

An underfill member 65 may extend between the upper semiconductor chip 60 and the lower die structure BD to reinforce a gap between the upper semiconductor chip 60 and the lower die structure BD. The underfill member may include a material with relatively high fluidity to effectively fill the small space between the upper semiconductor chip 60 and the lower die structure BD. For example, the underfill member may include an adhesive containing an epoxy material.

The second semiconductor chip 60 may be a second chiplet die (upper chiplet die). The second semiconductor chip 60 may be a small structural unit or IP block unit of a part of the processor chip. The second chiplet die may form one chip together with the first semiconductor chip as the first chiplet die.

The first semiconductor chip 20 may have a first size, and the second semiconductor chip 60 may have a second size greater than the first size. The first semiconductor chip 20 may have a first width, and the second semiconductor chip 60 may have a second width that is greater than the first width.

In example embodiments, the upper sealing member 80 may cover the lower die structure BD and the second semiconductor chip 60 on the lower redistribution wiring layer 10. The upper sealing member 80 may cover the side surface and an upper surface of the lower die structure BD and a side surface and an upper surface of the second semiconductor chip 60. The upper sealing member 80 may cover the side surface and the upper surface of the upper redistribution wiring layer 50 of the lower die structure BD.

For example, the upper sealing member 80 may include an epoxy mold compound (EMC). The upper sealing member 80 may include fillers and epoxy resin as a binder for the fillers. The upper sealing member 80 may have a second elastic modulus. The second elastic modulus of the upper sealing member 80 may be less than the first elastic modulus of the lower sealing member 40. The second elastic modulus may be within a range of 150×10³ kgf/mm² to 20×10³ kgf/mm². The second elastic modulus may be determined according to a content ratio of the fillers.

In example embodiments, the conductive wires 70 as the conductive ground structures may extend to the second bonding pads 56b in the second region R2 of the upper redistribution wiring layer 50 from the upper surface of the upper sealing member 80.

Each of the conductive wires 70 may includes a wire body extending in the vertical direction, a first bonding end portion provided at a first end portion of the wire body and bonded to the second bonding pad 56b, and a second bonding end portion provided at a second end portion of the wire body opposite to the first end portion and exposed from (i.e., exposed at) the upper surface of the upper sealing member 80.

As illustrated in FIG. 2, when viewed in plan view, the second semiconductor chip 60 may be disposed in the first region R1 of the upper redistribution wiring layer 50, and the plurality of conductive wires 70 may be disposed in the second region R2 of the upper redistribution wiring layer 50. The plurality of conductive wires 70 may be arranged around the second semiconductor chip 60 on the lower die structure BD. The number and spacing distances of the conductive wires 70 may be determined in consideration of the shielding effect according to frequency.

In example embodiments, the electromagnetic shielding layer 90 may be provided to cover an upper surface of the upper sealing member 80. The electromagnetic shielding layer 90 may be electrically connected to the conductive wires 70. The electromagnetic shielding layer 90 may be in direct contact with the second bonding end portion of the conductive wire 70. The electromagnetic shielding layer 90 may be grounded by the conductive wires 70, the upper redistribution wiring layer 50, the through vias 30, and the lower redistribution wiring layer 10.

The electromagnetic shielding layer 90 may include a conductive material. The conductive material may include metal such as copper, silver, stainless steel, etc. The electromagnetic shielding layer 90 may be formed by a coating process, a spray process, a plating process, a deposition process, etc. A thickness of the electromagnetic shielding layer 90 may be within a range of 10 μm to 100 μm.

In example embodiments, the conductive bumps 18 may be disposed on the outer surface of the lower redistribution wiring layer 10. For example, each of the conductive bumps 18 may include a pillar bump on the lower bonding pad 16 and a solder bump on the pillar bump. For example, the pillar bump may include copper (Cu), aluminum (Al), tin (Sn), nickel (Ni), gold (Au), platinum (Pt), or an alloy thereof. The solder bump may include solder. The semiconductor packaging device 200 may be mounted on a substrate such as a package substrate, an interposer, or a redistribution wiring layer via the conductive bumps 18 to form a semiconductor package.

As mentioned above, the semiconductor packaging device 200 may include the lower redistribution wiring layer 10, the lower die structure BD stacked on the lower redistribution wiring layer 10, the second semiconductor chip 60 stacked on the lower die structure BD, and the upper sealing member 80 covering the lower die structure BD and the second semiconductor chip 60 on the lower redistribution wiring layer 10. The lower die structure BD may include the lower sealing member 40 that accommodates the first semiconductor chip 20 (i.e., the first semiconductor chip 20 is contained within the lower sealing member 40) and the plurality of through vias 30, and the upper redistribution wiring layer 50 disposed on the lower sealing member 40.

Since the first elastic modulus of the lower sealing member 40 is greater than the second elastic modulus of the upper sealing member 80, impacts generated when bonding the second semiconductor chip 60 on the lower die structure BD may be prevented or reduced. The upper sealing member 80 may cover the upper redistribution wiring layer 50 of the lower die structure BD so that the upper redistribution wiring layer 50 is not exposed to the outside (i.e., not exposed to an external environment), to thereby prevent moisture absorption and improve reliability.

Further, the electromagnetic shielding layer 90 may cover the entire upper surface of the upper sealing member 80 and may be grounded by the conductive wires 70 as the conductive ground structures that extend within the upper sealing member 80. Thus, the electromagnetic shielding layer 90 may effectively shield electromagnetic waves emitted from the second semiconductor chip 60.

Hereinafter, a method of manufacturing the semiconductor packaging device of FIG. 1 will be described.

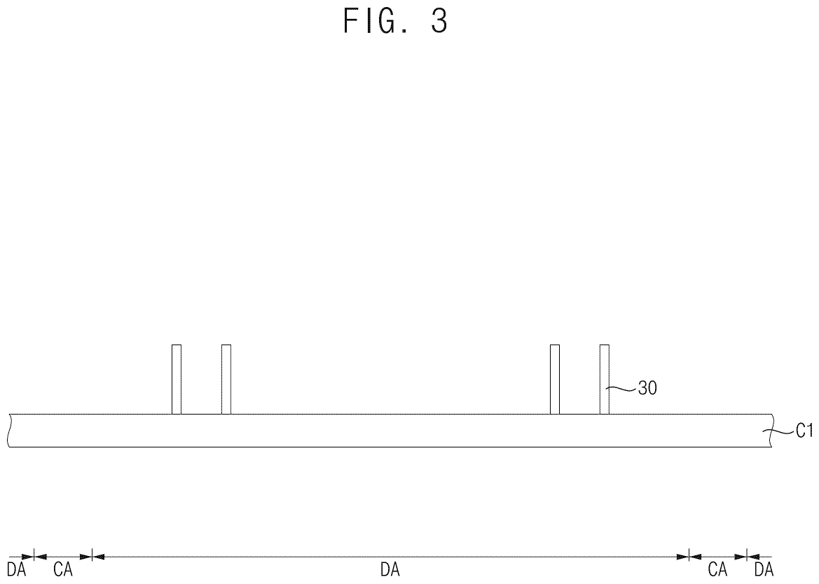

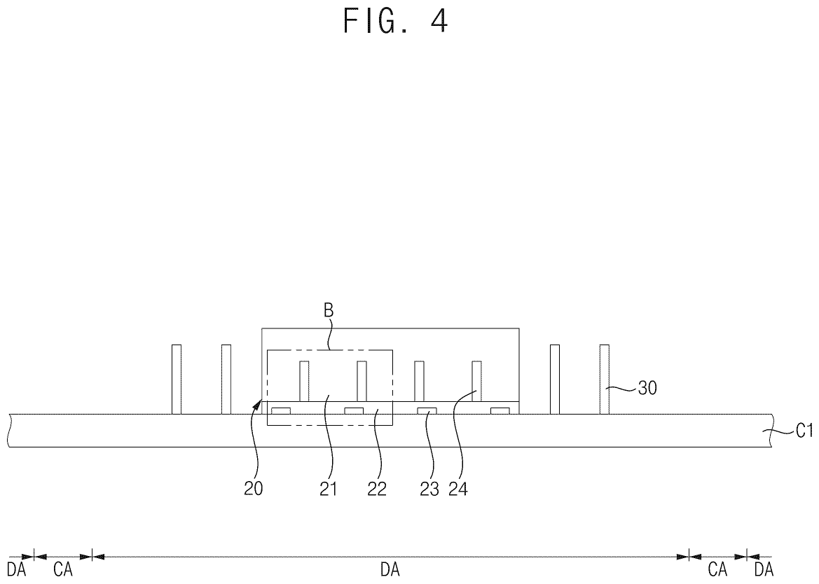

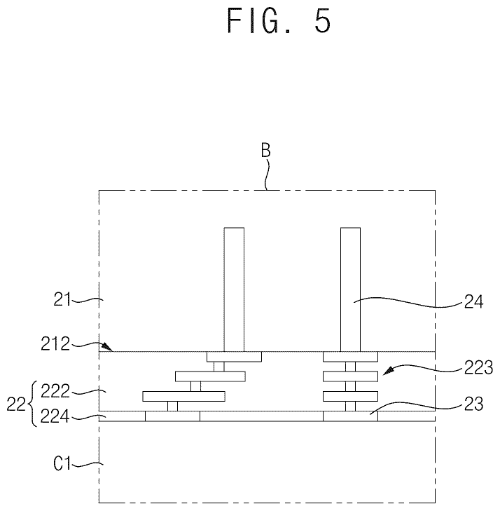

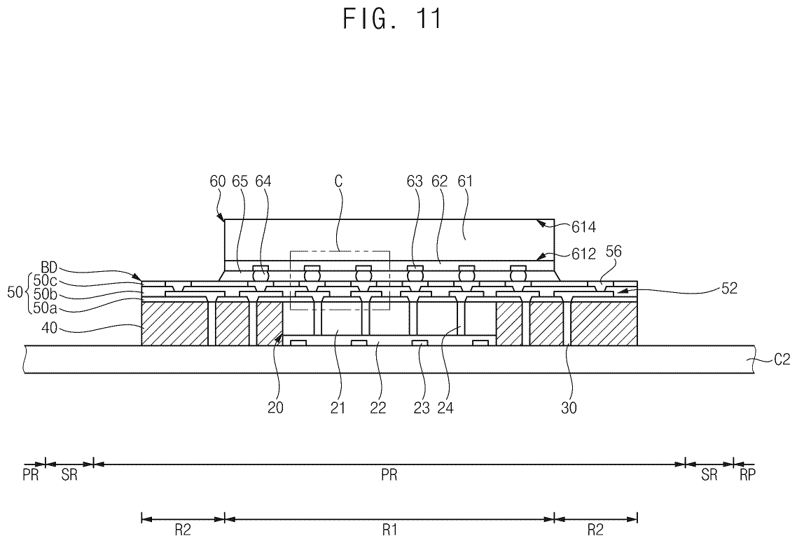

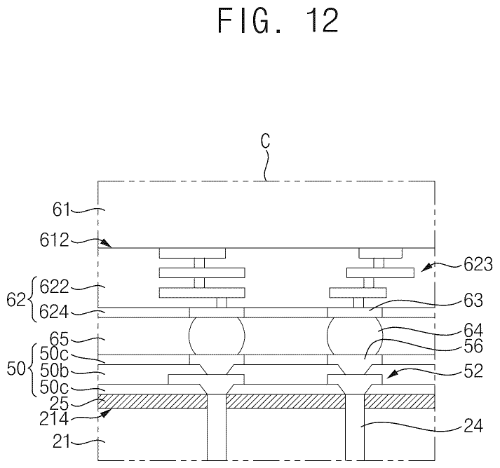

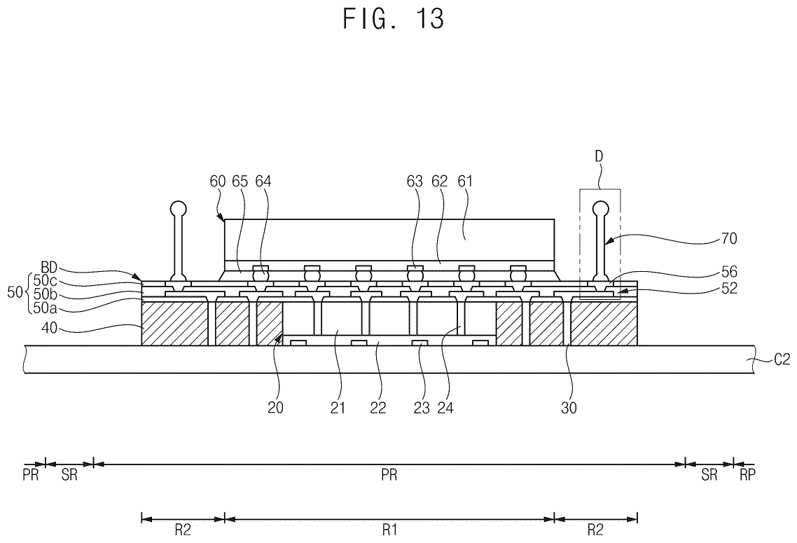

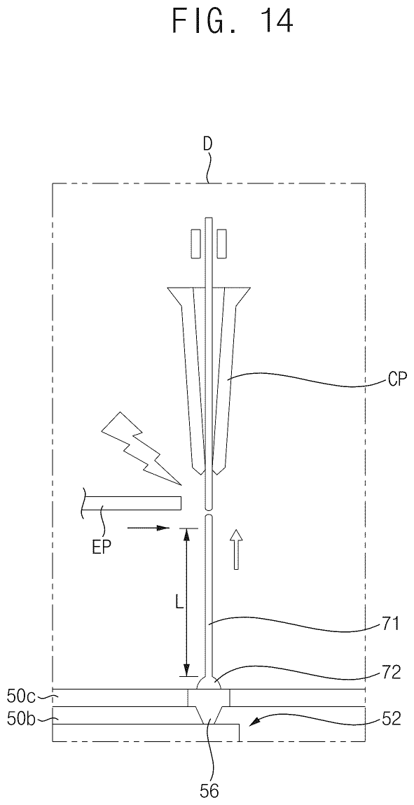

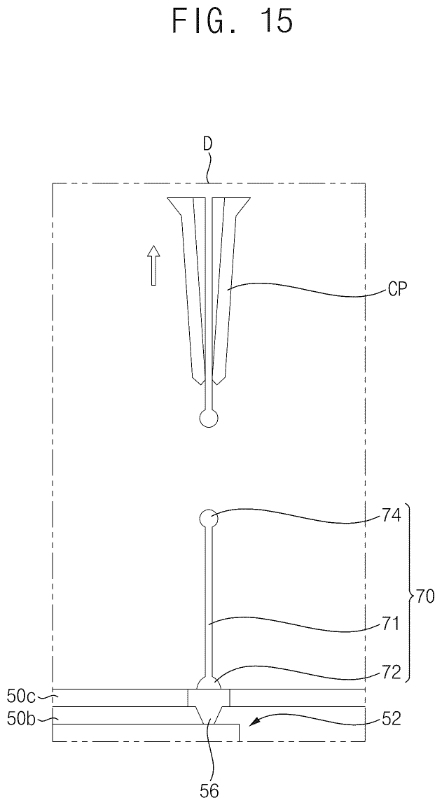

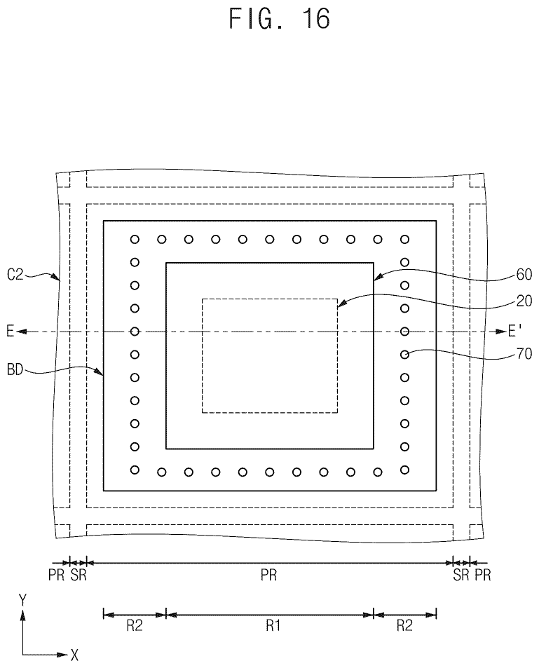

FIGS. 3 to 19 are views illustrating a method of manufacturing a semiconductor package in accordance with example embodiments. FIGS. 3, 4, 6 to 11, 13 and 17 to 19 are cross-sectional views illustrating a method of manufacturing a semiconductor package in accordance with example embodiments. FIG. 5 is an enlarged cross-sectional view illustrating portion ‘B’ in FIG. 4. FIG. 12 is an enlarged cross-sectional view illustrating portion ‘C’ in FIG. 11. FIGS. 14 and 15 are enlarged cross-sectional views illustrating portion ‘D’ in FIG. 13. FIG. 16 is a plan view of FIG. 13. FIG. 13 is a cross-sectional view taken along the line E-E′ in FIG. 16.

Referring to FIGS. 3 to 10, a lower die structure BD including a lower semiconductor chip 20 is formed therein may be formed.

As illustrated in FIG. 3, a plurality of through vias 30 as conductive structures may be formed on a first carrier substrate C1.

In example embodiments, the first carrier substrate C1 may be used as a base substrate on which a plurality of lower semiconductor chips are stacked and a molding member is formed to cover them. The first carrier substrate C1 may have a shape corresponding to a wafer on which a semiconductor process is performed. The first carrier substrate C1 may include a die region DA on which the lower semiconductor chip is mounted and a cutting region CA surrounding the die region DA. As will be described later, an upper redistribution wiring layer and the molding member formed on the first carrier substrate C1 may be cut along the cutting region CA that divides a plurality of the die regions DA to be individualized.

In particular, a seed layer and a photoresist layer may be formed on the first carrier substrate C1, and an exposure process may be performed on the photoresist layer to a photoresist pattern having openings that expose regions for forming the plurality of through vias 30 in a fan-out region.

Then, an electrolytic plating process may be performed to fill the openings of the photoresist pattern with a conductive material to form the through vias 30. Then, the photoresist pattern may be removed by a strip process, and portions of the seed layer exposed by the through vias 30 may be removed.

For example, a height, that is, a length of the through via 30 from the first carrier substrate C1 may be within a range of 50 μm to 150 μm. A diameter of the through via 30 may be within a range of 20 μm to 100 μm.

As illustrated in FIGS. 4 and 5, at least one lower semiconductor chip 20 may be disposed on the first carrier substrate C1.

In example embodiments, the lower semiconductor chip 20a individualized from a wafer through a sawing process may be placed in a fan-in region of the first carrier substrate C1. The plurality of through vias 30 may be arranged around the lower semiconductor chip 20. The lower semiconductor chip 20 may be stacked such that a front surface of the lower semiconductor chip faces the first carrier substrate C1. The lower semiconductor chip 20 may be a first chiplet die (lower chiplet die). The lower semiconductor chip 20 may be a small structural unit or IP block unit as a part of a processor chip. The first chiplet die may form one chip together with the upper semiconductor chip as a second chiplet die.

As illustrated in FIG. 5, the lower semiconductor chip 20 may include a first substrate 21 and a first front insulating layer 22 having first chip pads 23 on an outer surface thereof. Additionally, the lower semiconductor chip 20 may include a plurality of through electrodes 24 that are provided in the first substrate 21 and are electrically connected to the first chip pads 23.

The first substrate 21 may have a first surface 212 and a second surface 214 opposite to the first surface 212. Circuit patterns may be formed on the first surface 212 of the first substrate 21. For example, the first substrate 21 may include silicon, germanium, silicon-germanium, or III-V compounds, e.g., GaP, GaAs, GaSb, etc. In some embodiments, the second substrate 21 may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the first semiconductor chip may be a semiconductor device in which a plurality of circuit elements are formed. The circuit patterns may be formed by performing a Fab process called a Front End of Line (FEOL) process for manufacturing semiconductor devices on the first surface 212 of the first substrate 21. A surface of the first substrate on which the FEOL process is performed may be referred to as a front surface of the first substrate, and a surface opposite to the front surface may be referred to as a backside surface.

The first front insulating layer 22 as an insulation interlayer may be formed on the first surface 212 of the first substrate 21, that is, the front surface. The first front insulating layer 22 may include a plurality of insulating layers 222 and 224 and wirings 223 in the insulating layers. In addition, the first chip pads 23 may be provided in an outermost insulating layer of the first front insulating layer 22.

For example, the first front insulating layer 22 may include a first metal wiring layer 222 and a first passivation layer 224. The first metal wiring layer 222 may include a plurality of wirings 223 therein. For example, the first metal wiring layer 222 may include a metal wiring structure having the plurality of wirings 223 vertically stacked in buffer layers and insulating layers. The first chip pad 23 may be formed on an uppermost wiring among the plurality of wirings 223. For example, the wirings may include aluminum (Al), copper (Cu), tin (Sn), nickel (Ni), gold (Au), platinum (Pt), or an alloy thereof.

The first passivation layer 224 may be formed on the first metal wiring layer 222 and may expose at least a portion of the first chip pad 23. The first passivation layer 224 may include a plurality of stacked insulating layers. For example, the first passivation layer 224 may include an oxide layer, silicon nitride or silicon carbonitride. The first passivation layer 224 may have a single-layer or multi-layer structure.

The first chip pad 23 may be provided in the first passivation layer 224. The first chip pad 23 may be exposed through an outer surface of the first passivation layer 224. Although not illustrated in the figures, an insulation interlayer may be provided on the first surface 212 of the first substrate 21 to cover the circuit patterns. The insulation interlayer may be formed of, for example, silicon oxide or a low dielectric material. The insulation interlayer may include lower wirings therein that are electrically connected to the circuit patterns. Accordingly, the circuit pattern may be electrically connected to the first chip pad 23 by the lower wirings and the wirings.

The through electrode 24 such as through silicon via (TSV) may vertically penetrate the insulation interlayer and may extend from the first surface 212 of the first substrate 21 to a predetermined depth. The through electrode 24 may contact a lowest wiring of the metal wiring structure. Accordingly, the through electrode 24 may be electrically connected to the first chip pad 23 through the wirings 223.

A liner layer (not illustrated) may be provided on an outer surface of the through electrode 24. The liner layer may include silicon oxide or carbon-doped silicon oxide. The liner layer may electrically insulate the through electrode 24 from the first substrate 21 and the first metal wiring layer 222.

The through electrode 24 and the first chip pad 22 may include the same metal. For example, the metal may include copper (Cu). However, it may not be limited thereto.

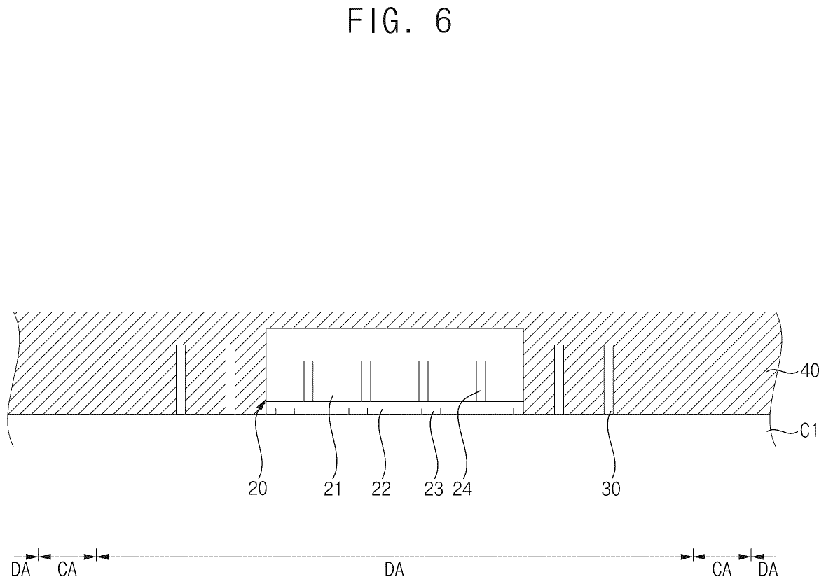

As illustrated in FIG. 6, a lower sealing member 40 may be formed on the first carrier substrate C1 to cover the lower semiconductor chip 20 and the plurality of through vias 30. The lower sealing member 40 may be formed to cover upper surfaces of the lower semiconductor chip 20 and the plurality of through vias 30. For example, the lower sealing member 40 may include an epoxy mold compound (EMC). The lower sealing member 40 may include fillers and epoxy resin as a binder for the fillers. The lower sealing member 40 may have a first elastic modulus. The first elastic modulus may be within a range of 20×10³ kgf/mm² to 27×10³ kgf/mm². The first elastic modulus may be determined according to a content ratio of the fillers.

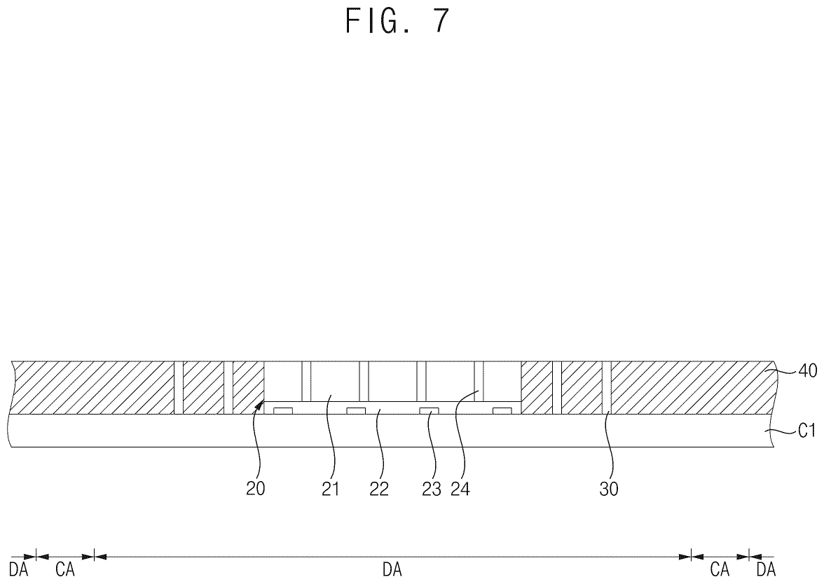

As illustrated in FIG. 7, an upper portion of the lower sealing member 40 and the second surface 214 of the first substrate 21 may be partially removed to expose end portions of the through electrodes 24 and end portions of the through vias 30.

In example embodiments, first, a grinding process such as a back lap process may be performed to partially remove the upper portion of the lower sealing member 40 and the second surface 214 of the first substrate 21, and then an etching process such as a silicon recess process may be performed to expose the end portions of the through electrodes 24 and the through vias 30. Accordingly, a thickness of the first substrate 21 may be reduced to a desired thickness. For example, the thickness of the first substrate 21 may be in a range of from about 30 μm to about 150 μm.

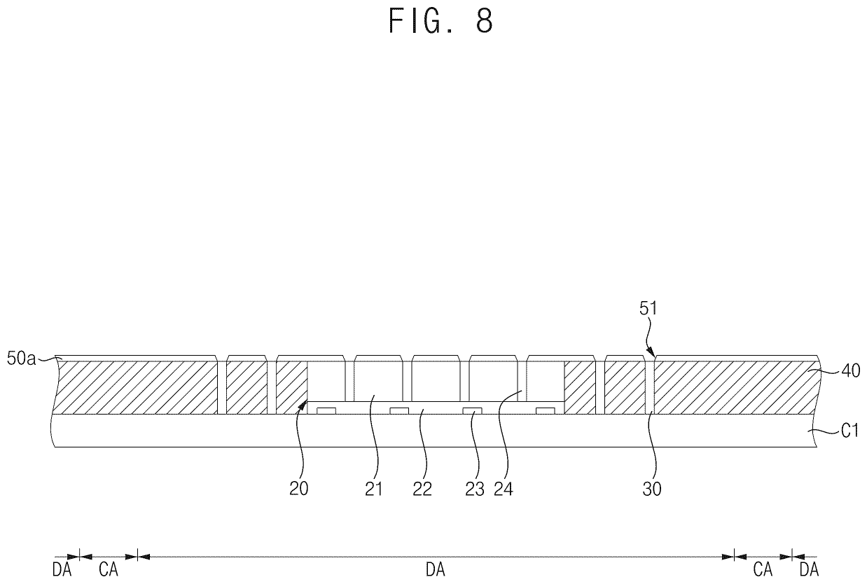

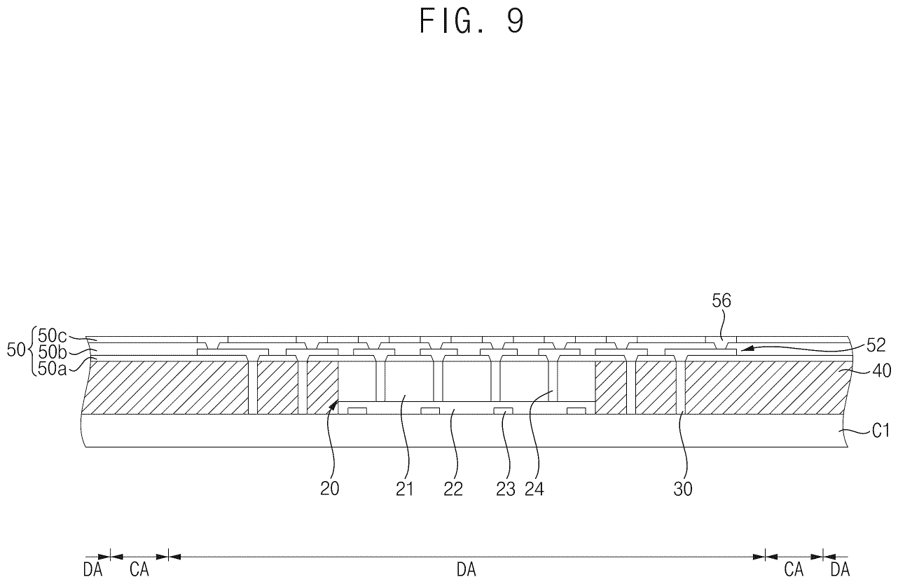

As illustrated in FIGS. 8 and 9, an upper redistribution wiring layer 50 having upper redistribution wirings 52 may be formed on an upper surface of the lower sealing member 40 and the backside surface of the lower semiconductor chip 20. The redistribution wirings 52 may be electrically connected to the through electrodes 24 and the through vias 30.

As illustrated in FIG. 8, after a first upper insulating layer 50a is formed on the upper surface of the lower sealing member 40, the first upper insulating layer 500a may be patterned to form openings 51 that expose the end portions of the through electrodes 24 and the through vias 30. The first upper insulating layer 50a may include a polymer, a dielectric layer, etc. The first upper insulating layer 50a may be formed by a vapor deposition process, a spin coating process, etc.

As illustrated in FIG. 9, after a seed layer is formed on portions of the through electrodes 24 and portions of the through vias 30 exposed by the openings 51 and within the openings 51, the seed layer may be patterned and an electrolytic plating process may be performed to form the upper redistribution wirings 52. Accordingly, at least portions of the upper redistribution wirings 52 may be electrically connected to the through electrodes 24 and the through vias 30 through the openings 51. The upper redistribution wiring may include aluminum (Al), copper (Cu), tin (Sn), nickel (Ni), gold (Au), platinum (Pt), or an alloy thereof.

In this embodiment, the upper redistribution wiring layer is illustrated as including one layer of upper redistribution wirings 52, but it is not limited thereto, and the upper redistribution wiring layer may include at least two layers of stacked upper redistribution wirings.

Then, upper bonding pads 56 may be formed on uppermost redistribution wirings 52.

For example, a second upper insulating layer 50b may be formed on the first upper insulating layer 50a to cover the upper redistribution wirings 52, and the second upper insulating layer 50b may be patterned to form openings that expose the upper redistribution wirings 52. The upper redistribution wirings 52 exposed by the openings may be the uppermost redistribution wirings. A portion of the uppermost redistribution wiring may include a redistribution pad portion.

Then, a seed layer may be formed on the second upper insulating layer 50b, and a photoresist pattern having openings that expose upper bonding pad regions may be formed on the seed layer. The upper bonding pads 56 may be formed within the openings of the photoresist pattern through a plating process. The upper bonding pads may include a metal material. The upper bonding pads may include the same material as the upper redistribution wirings 52. The upper bonding pads may include copper (Cu). Then, after removing the photoresist pattern, portions of the seed layer exposed by the upper bonding pads may be removed.

Accordingly, the upper bonding pads 56 may be formed on the uppermost redistribution wirings 52 of the upper redistribution wiring layer 50. The upper bonding pads 56 may be exposed from (i.e., exposed at) an upper surface of the upper redistribution wiring layer 50. When viewed in plan view, the upper redistribution wiring layer 50 may include a first region R1 overlapping the upper semiconductor chip and a second region R2 surrounding the first region R1. The upper bonding pads 56 may include first bonding pads 56a disposed in the first region R1 for connection to the upper semiconductor chip and second upper bonding pads 56b disposed in the second region R2 for connection to conductive wires as conductive ground structures.

For example, the upper bonding pads 56 may have a multilayer structure. The upper bonding pad 56 may include a bonding pad pattern and a plating pad pattern formed on the bonding pad pattern. The bonding pad pattern may include copper (Cu), and the plating pad pattern may include nickel (Ni), gold (Au), or titanium (Ti).

The first bonding pads 56a may be pads for electrical connection between the lower semiconductor chip and the upper semiconductor chip and between the through via and the upper semiconductor chip, and the second bonding pads 56b may be pads for electrical connection between the through via and the conductive wire. First pads of the first bonding pads 56a may be electrically connected to the first chip pads 23 by the upper redistribution wirings 52 and the through electrodes 24, and second pads of the first bonding pads 56a may be electrically connected to the through vias 30 by the upper redistribution wirings 52. Additionally, the second bonding pad 56b may be electrically connected to the through via 30 through the upper redistribution wiring 52.

It will be understood that the number, size, and arrangement of the upper insulating layers and the upper redistribution wirings of the upper redistribution wiring layer are provided as examples, and the present inventive concept is not limited thereto.

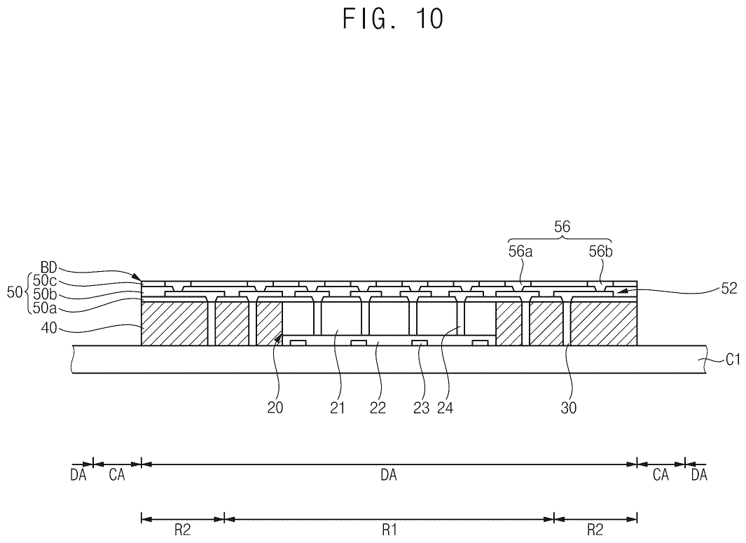

As illustrated in FIG. 10, the lower sealing member 40 and the upper redistribution wiring layer 50 may be cut along the cutting region CA through a sawing process to form the lower die structure BD. The lower die structure BD may include the lower semiconductor chip 20, the lower sealing member 40 surrounding the lower semiconductor chip 20, the plurality of through vias 30 in the lower sealing member 40, and the upper redistribution wiring layer 50 formed on the lower sealing member 40.

Referring to FIGS. 11 and 12, an upper semiconductor chip 60 may be mounted on the lower die structure BD. The lower die structure BD may be placed on a second carrier substrate C2, and the upper semiconductor chip 60 individualized through a sawing process from a wafer may be bonded onto the lower die structure BD by a chip-on-wafer bonding method. The upper semiconductor chip 60 may be disposed in the first region R1 on the upper redistribution wiring layer 50.

In example embodiments, the second carrier substrate C2 may be used as a base substrate on which a plurality of the lower die structures are arranged, the upper semiconductor chip is stacked on the lower die structure and an upper molding member is formed to cover them. The second carrier substrate C2 may have a shape corresponding to a wafer on which a semiconductor process is performed. The second carrier substrate C2 may include a package region PR on which the lower die structure is mounted and a scribe lane region SR surrounding the die region PR. As will be described later, the upper molding member formed on the second carrier substrate C2 may be cut along the scribe lane region SR that divides a plurality of the package regions PR to be individualized.

As illustrated in FIG. 11, the upper semiconductor chip 60 may be mounted on the lower die structure BD by a flip chip bonding method. Second chip pads 63 of the upper semiconductor chip 60 may be electrically connected to the first bonding pads 56a in the first region R1 of the upper redistribution wiring layer 50 of the lower die structure BD by conductive bumps 64. The conductive bumps 64 may be formed on the second chip pads 63 of the upper semiconductor chip 60, respectively. For example, each of the conductive bumps 64 may include a pillar bump on the second chip pad 63 and a solder bump on the pillar bump. The pillar bump may include copper (Cu), aluminum (Al), tin (Sn), nickel (Ni), gold (Au), platinum (Pt), or an alloy thereof. The solder bump may include solder.

Then, a dispenser nozzle may be moved along edges of the upper semiconductor chip 60 to dispense an underfill solution between the upper semiconductor chip 60 and the lower die structure BD, and the underfill solution may be hardened to form an underfill member 65. The underfill member 65 may extend between the upper semiconductor chip 60 and the lower die structure BD to reinforce a gap between the upper semiconductor chip 60 and the lower die structure BD. The underfill member may include a material having relatively high fluidity to effectively fill the small space between the upper semiconductor chip 60 and the lower die structure BD. For example, the underfill member may include an adhesive containing an epoxy material.

As illustrated in FIG. 12, the upper semiconductor chip 60 may include a second substrate 61 and a second front insulating layer 62 having the second chip pads 63 on an outer surface thereof. The second substrate 61 may have a first surface 612 and a second surface 614 opposite to the first surface 612. Circuit patterns may be formed on the first surface 612 of the second substrate 61.

The second front insulating layer 62 as an insulation interlayer may be formed on the first surface 612 of the second substrate 61, that is, a front surface. The second front insulating layer 62 may include a plurality of insulating layers 622 and 624 and wirings 623 in the insulating layers. In addition, the second chip pads 63 may be provided in an outermost insulating layer of the second front insulating layer 62.

For example, the second front insulating layer 62 may include a second metal wiring layer 622 and a third passivation layer 624. The second metal wiring layer 622 may include a plurality of wirings 623 therein. For example, the second metal wiring layer 622 may include a metal wiring structure having the plurality of wirings 623 vertically stacked in buffer layers and insulating layers. The second chip pad 63 may be formed on an uppermost wiring among the plurality of wirings 623. For example, the wirings may include aluminum (Al), copper (Cu), tin (Sn), nickel (Ni), gold (Au), platinum (Pt), or an alloy thereof.

The third passivation layer 624 may be formed on the second metal wiring layer 622 and may expose at least a portion of the second chip pad 63. The third passivation layer 624 may include a plurality of stacked insulating layers. For example, the third passivation layer 624 may include an oxide layer, silicon nitride or silicon carbonitride. The third passivation layer 624 may have a single-layer or multi-layer structure.

The second chip pad 63 may be provided in the third passivation layer 624. The second chip pad 63 may be exposed through an outer surface of the third passivation layer 624. Although not illustrated in the figures, an insulation interlayer may be provided on the first surface 612 of the second substrate 61 to cover the circuit patterns. The insulation interlayer may be formed of, for example, silicon oxide or a low dielectric material. The insulation interlayer may include lower wirings therein that are electrically connected to the circuit patterns. Accordingly, the circuit pattern may be electrically connected to the second chip pad 63 by the lower wirings and the wirings.

The upper semiconductor chip 60 may be a second chiplet die (upper chiplet die). The upper semiconductor chip 60 may be a small structural unit or IP block unit of a part of the processor chip. The second chiplet die may form one chip together with the lower semiconductor chip as the first chiplet die.

The lower semiconductor chip 20 may have a first size, and the upper semiconductor chip 60 may have a second size greater than the first size. The lower semiconductor chip 20 may have a first width, and the upper semiconductor chip 60 may have a second width that is greater than the first width.

Referring to FIGS. 13 to 16, conductive wires 70 as the conductive ground structures may be formed on the lower die structure BD. The conductive wires 70 may be formed in the second region R2 of the upper redistribution wiring layer 50.

In example embodiments, the conductive wires 70 may be formed by a bonding wire process. The conductive wires 70 may be bonding wires formed by the bonding wire process.

As illustrated in FIGS. 14 and 15, after one end portion of a wire drawn from a capillary CP is bonded to the second bonding pad 56b of the upper redistribution wiring layer 50 in the second region R2, and then the capillary CP may move in an upward vertical direction to withdraw the wire. The wire may be pulled out while moving in the vertical direction. Then, when the wire is extended by a predetermined length L, a portion of the wire may be cut to form the conductive wire 70. When cutting a portion of the wire, a free air ball FAB may be formed in the cut portion of the wire. For example, an Electronic Flame-Off (EFO) electrode (EP) may be moved adjacent to the cut portion (free end) of the wire and a spark may be generated between the EFO electrode (EP) and the cut portion of the wire to from a ball at a new free end.

Thus, the conductive wire 70 may include a wire body 71 extending in the vertical direction, a first bonding end portion 72 provided at a first end portion of the wire body 71 and bonded to the upper bonding pad 56, and a second bonding end portion 74 provided at a second end portion opposite to the first end portion of the wire body 71 and having a ball shape. A diameter of the conductive wire 70 may be within a range of 15 μm to 50 μm. The length of the conductive wire 70 may be within a range of 100 μm to 150 μm.

As illustrated in FIG. 16, the upper semiconductor chip 60 may be disposed in the first region R1 on the upper redistribution wiring layer 50, and the plurality of conductive wires 70 may be disposed in the second region R2 on the upper redistribution wiring layer 50. The plurality of conductive wires 70 may be arranged around the upper semiconductor chip 60 on the lower die structure BD. The number and spacing distances of the conductive wires 70 may be determined in consideration of the shielding effect according to frequency.

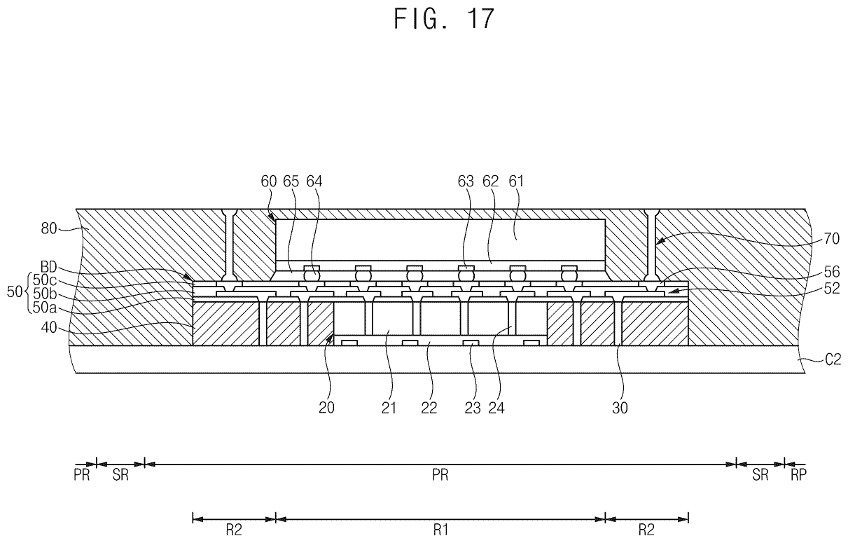

Referring to FIG. 17, an upper sealing member 80 may be formed on the upper surface of the second carrier substrate C2 to cover the lower die structure BD, the upper semiconductor chip 60, and the conductive wires 70.

For example, a sealing material may be formed on the upper surface of the second carrier substrate C2 to cover the lower die structure BD, the upper semiconductor chip 60, and the conductive wires 70, and an upper portion of the sealing material may be removed to form the upper sealing member 80 having a desired height. The upper sealing member 80 may be formed to expose end portions of the conductive wires 70, that is, the second bonding end portions 74.

For example, the upper sealing member 80 may include an epoxy mold compound (EMC). The upper sealing member 80 may include fillers and epoxy resin as a binder for the fillers. The upper sealing member 80 may have a second elastic modulus. The second elastic modulus of the upper sealing member 80 may be less than the first elastic modulus of the lower sealing member 40. The second elastic modulus may be within a range of 150×10³ kgf/mm² to 20×10³ kgf/mm². The second elastic modulus may be determined according to a content ratio of the fillers.

Since the first elastic modulus of the lower sealing member 40 is greater than the second elastic modulus of the upper sealing member 80, impacts generated when bonding the upper semiconductor chip 60 on the lower die structure BD may be prevented or reduced. The upper sealing member 80 may cover the upper redistribution wiring layer 50 of the lower die structure BD so that the upper redistribution wiring layer 50 is not exposed to the outside, to thereby prevent moisture absorption and improve reliability.

Thus, a sealing structure including the lower die structure BD and the upper sealing member 80 covering the lower die structure BD, the upper semiconductor chip 60 mounted on the lower die structure BD, and the conductive wires 80 extending upward from the lower die structure BD may be formed.

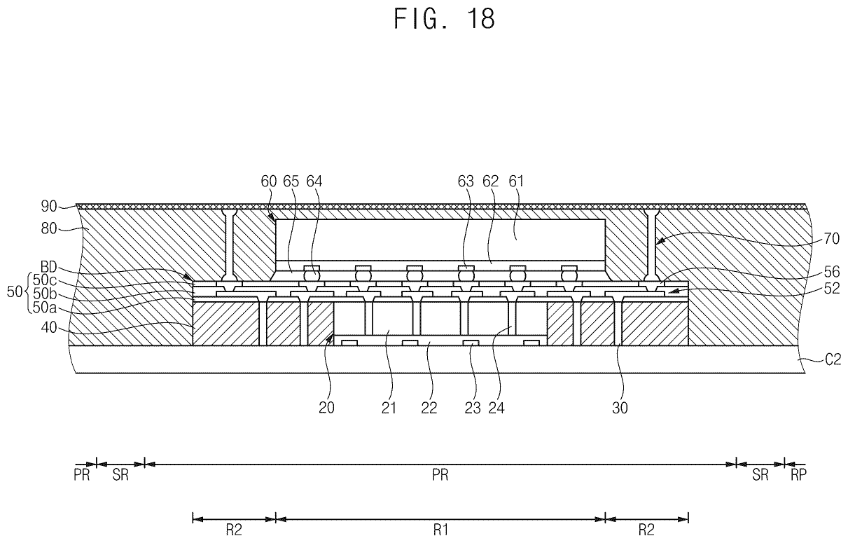

Referring to FIG. 18, an electromagnetic shielding layer 90 may be formed on the sealing structure.

In example embodiments, the electromagnetic shielding layer 90 may be formed by stacking a metal layer on an upper surface of the upper sealing member 80. The electromagnetic shielding layer 90 may include a conductive material. The conductive material may include metal such as copper, silver, stainless steel, etc. The electromagnetic shielding film layer 90 may be formed by a coating process, a spray process, a plating process, a deposition process, etc. A thickness of the electromagnetic shielding layer 90 may be within a range of 10 μm to 100 μm.

For example, the sealing structure supported on the second carrier substrate C2 may be loaded into a sputtering chamber, and particles sputtered from a target placed on a target holder may be evenly deposited on the upper surface of the upper sealing member 80 and the exposed surfaces of the second bonding end portions 74 of the conductive wires 70.

The electromagnetic shielding layer 90 may be electrically connected to the through via 30 by the conductive wires 70, the upper bonding pad 56 of the upper redistribution wiring layer 50, and the upper redistribution wiring 52.

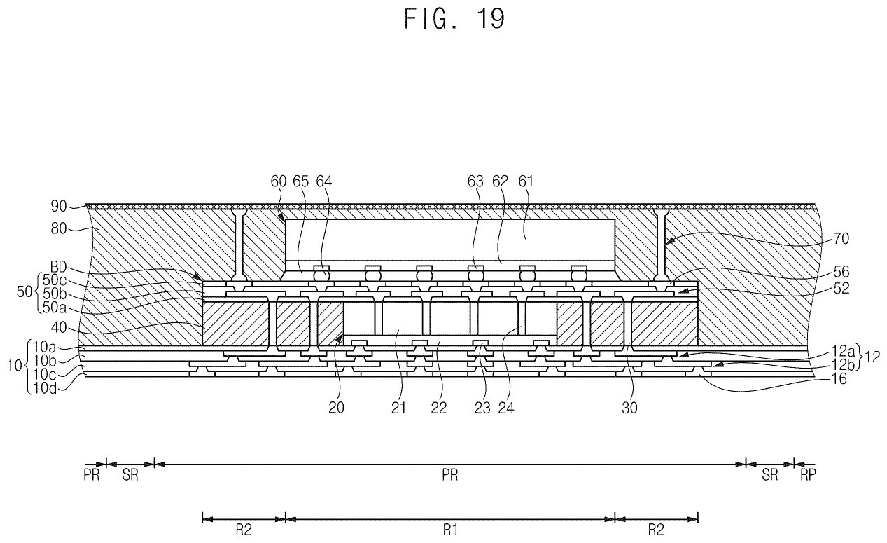

Referring to FIG. 19, a lower redistribution wiring layer 10 having lower redistribution wirings 12 may be formed on a lower surface of the sealing structure. The lower redistribution wiring layer 10 may be formed on a lower surface of the lower sealing member 40, the front surface of the lower semiconductor chip 20, and a lower surface of the upper sealing member 80.

In example embodiments, the structure of FIG. 18 may be turned over, the second carrier substrate C2 may be removed to expose the lower surface of the sealing structure, and then the sealing structure may be placed on a third carrier substrate such that the lower surface of the sealing structure faces upward. Then, after forming a first lower insulating layer 10a on the lower surface of the lower sealing member 40, the front surface of the lower semiconductor chip 20, and the lower surface of the upper sealing member 80, the first lower insulating layer 10a may be patterned to form openings that expose the through vias 30 and the first chip pads 23, respectively. Some of the openings of the patterned first upper insulating layer 10a may expose the through vias 30 and others of the openings may expose the first chip pads 23.

After forming a seed layer on the through vias 30 and the first chip pads 23 and in the openings, the seed layer may be patterned and an electrolytic plating process may be performed to form the first lower redistribution wirings 12a. Accordingly, at least portions of the first lower redistribution wirings 12a may directly contact the through vias 30 and the first chip pads 23 through the openings.

Similarly, after forming a second lower insulating layer 10b on the first lower insulating layer 10a to cover the first lower redistribution wirings 12a, the second lower insulating layer 10b may be patterned to form openings that expose the first lower redistribution wirings 12a. Then, second lower redistribution wirings 12b may be formed on the second lower insulating layer 10b to be electrically connected to the first lower redistribution wirings 12a through the openings, respectively.

In this embodiment, the lower redistribution wiring layer is illustrated as including two layers of lower redistribution wirings 12, but is not limited thereto, and the lower redistribution wiring layer may have at least two layers of stacked lower redistribution wirings.

Then, lower bonding pads 16 may be formed on uppermost lower redistribution wirings 12b.

For example, a third lower insulating layer 10c may be formed on the second lower insulating layer 10b to cover the second lower redistribution wirings 12b, and the third lower insulating layer 10c may be patterned to form openings that expose the second lower redistribution wirings 12b. The second lower redistribution wirings 12b exposed by the openings may be uppermost redistribution wirings. A portion of the uppermost redistribution wiring may include a redistribution pad portion.

Then, a seed layer may be formed on the third lower insulating layer 50c, and a photoresist pattern having openings that expose lower bonding pad regions may be formed on the seed layer. The lower bonding pads 16 may be formed within the openings of the photoresist pattern through a plating process. The lower bonding pads may include a metal material. The lower bonding pads may include the same material as the lower redistribution wirings 12. The lower bonding pads may include copper (Cu). Then, after removing the photoresist pattern, portions of the seed layer exposed by the lower bonding pads may be removed.

Then, a fourth lower insulating layer 10d may be formed on the third lower insulating layer 10c and may expose at least a portion of the lower bonding pad 16. The fourth lower insulating layer 10d may function as a passivation layer.

Accordingly, the lower redistribution wiring layer 10 having the first to fourth lower insulating layers 10a, 10b, 10c, and 10d may be formed. The lower redistribution wiring layer 10 may include the lower redistribution wirings 12. The lower bonding pads 16 may be exposed from a lower surface of the lower redistribution wiring layer 10.

Then, conductive bumps may be formed on the lower bonding pads 16 of the lower redistribution wiring layer 10.

For example, a seed layer and a photoresist layer may be formed on the lower surface of the lower redistribution wiring layer 10, and an exposure process may be performed to form a photoresist pattern having openings that expose bump regions. After filling the openings of the photoresist pattern with a conductive material, the photoresist pattern may be removed and a reflow process may be performed to form the conductive bumps 50. Alternatively, the conductive bumps may be formed by a screen printing process, a deposition process, etc.

For example, a pillar bump may be formed on the lower bonding pad 16 of the lower redistribution wiring layer 10, and a solder bump may be formed on the pillar bump.

Then, the sealing structure may be cut along the scribe lane region SR to form a stack semiconductor chip 200 (see FIG. 1) as a chiplet package including the lower die structure BD having the first chiplet die 20 therein and the second chiplet die 20b stacked on the lower die structure BD.

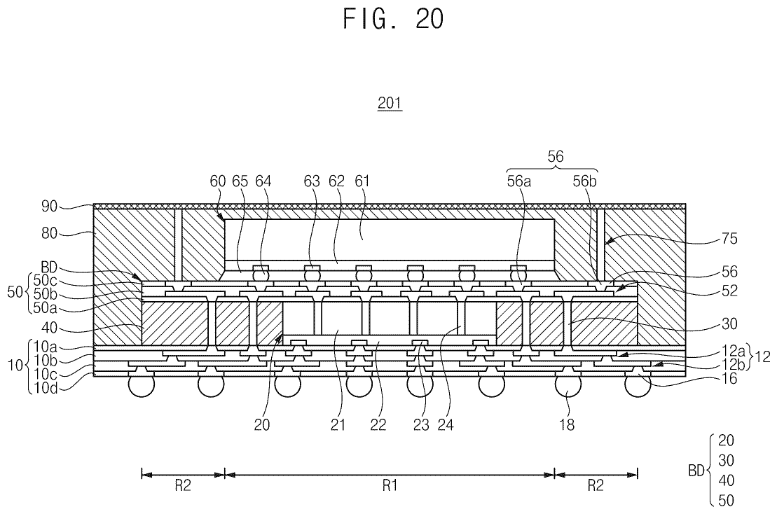

FIG. 20 is a cross-sectional view illustrating a semiconductor packaging device in accordance with example embodiments. The semiconductor packaging device is substantially the same as or similar to the semiconductor packaging device described with reference to FIG. 1 except for configurations of conductive ground structures. Thus, same reference numerals will be used to refer to the same or like elements and any further repetitive explanation concerning the above elements will be omitted.

Referring to FIG. 20, a semiconductor packaging device 201 may include conductive pillars 75 that serve as conductive ground structures.

In example embodiments, the conductive pillars 75 may extend from second bonding pads 56b in a second region R2 of an upper redistribution wiring layer 50 to an upper surface of the upper sealing member 80. Each of the conductive pillars 75 may include a pillar body extending in a vertical direction, a first bonding end portion provided at a first end portion of the pillar body and bonded to the second bonding pad 56b, and a second bonding end portion provided at a second end portion opposite to the first end portion of the pillar body and exposed from the upper surface of the upper sealing member 80.

An electromagnetic shielding layer 90 may be provided to cover the upper surface of the upper sealing member 80. The electromagnetic shielding layer 90 may be electrically connected to the conductive pillars 75. The electromagnetic shielding layer 90 may be in direct contact with the second bonding end portion of the conductive pillar 75.

Hereinafter, a method of manufacturing the semiconductor packaging device of FIG. 20 will be described.

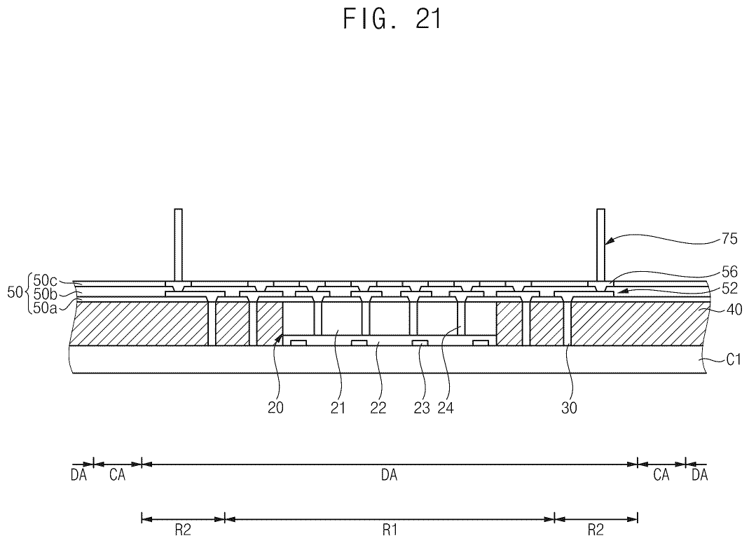

FIGS. 21 to 24 are cross-sectional views illustrating a method of manufacturing a semiconductor package in accordance with example embodiments.

Referring to FIG. 21, processes the same as or similar to the processes described with reference to FIGS. 3 to 9 may be performed to form a lower sealing member 40 that accommodate a lower semiconductor chip 20 and a plurality of through vias 30 on a first carrier substrate C1 and to form an upper redistribution wiring layer 50 on the lower sealing member 40, and conductive pillars 75 as conductive ground structures on the upper redistribution wiring layer 50.

In example embodiments, a photoresist layer may be formed on the upper redistribution wiring layer 50, and an exposure process may be performed on the photoresist layer to form a photoresist pattern having openings that expose regions for forming second bonding pads 56b in a second region.

Then, an electrolytic plating process may be performed to fill the openings of the photoresist pattern with a conductive material to form the conductive pillars 75. Then, the photoresist pattern may be removed by a strip process.

For example, a height, that is, a length, of the conductive pillar 75 from the upper redistribution wiring layer 50 may be within a range of 100 μm to 150 μm. A diameter of the through via 30 may be in a range of 20 μm to 100 μm.

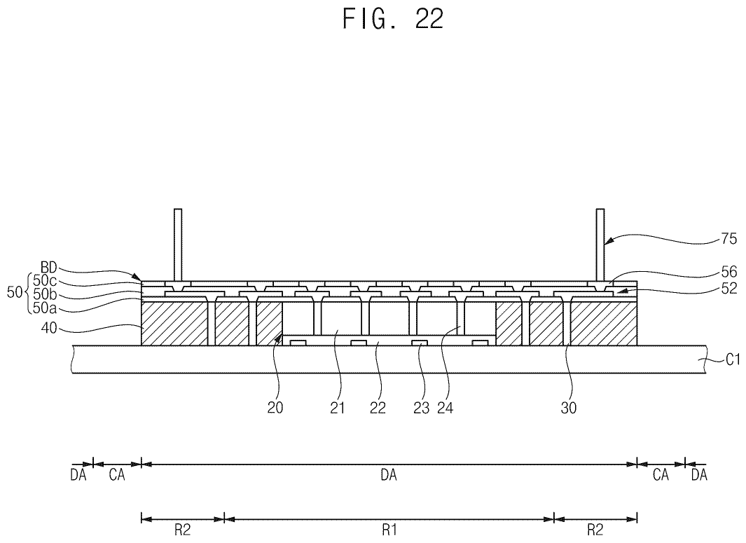

Referring to FIG. 22, the lower sealing member 40 and the upper redistribution wiring layer 50 may be cut along a cutting region CA through a sawing process to form a lower die structure BD. The lower die structure BD may include the lower semiconductor chip 20, the lower sealing member 40 surrounding the lower semiconductor chip 20, the plurality of through vias 30 within the lower sealing member 40, the upper redistribution wiring layer 50 formed on the lower sealing member 40, and the plurality of conductive pillars 75 formed on the upper redistribution wiring layer 50.

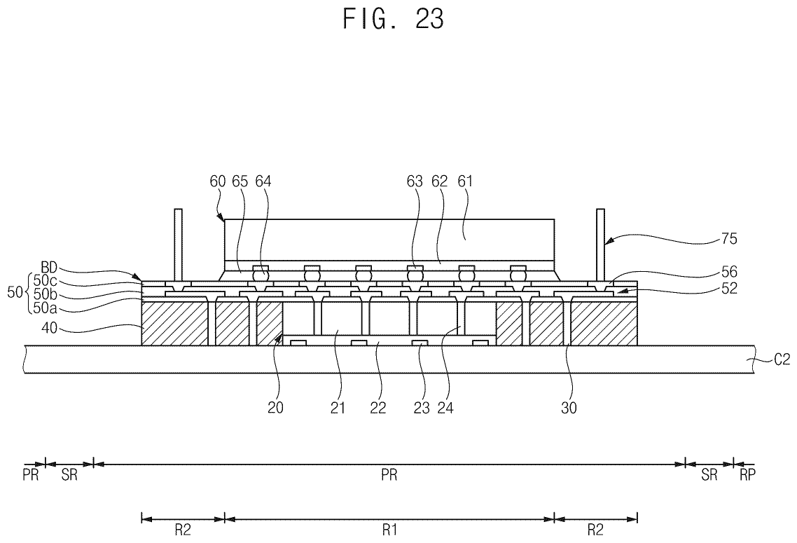

Referring to FIG. 23, processes the same as or similar to the processes described with reference to FIGS. 11 and 12 may be performed to mount an upper semiconductor chip 60 on the lower die structure BD. The lower die structure BD may be placed on a second carrier substrate C2, and the upper semiconductor chip 60 individualized from a wafer through a sawing process may be bonded onto the lower die structure BD by a chip-on-wafer bonding method. The upper semiconductor chip 60 may be disposed in a first region R1 on the upper redistribution wiring layer 50.

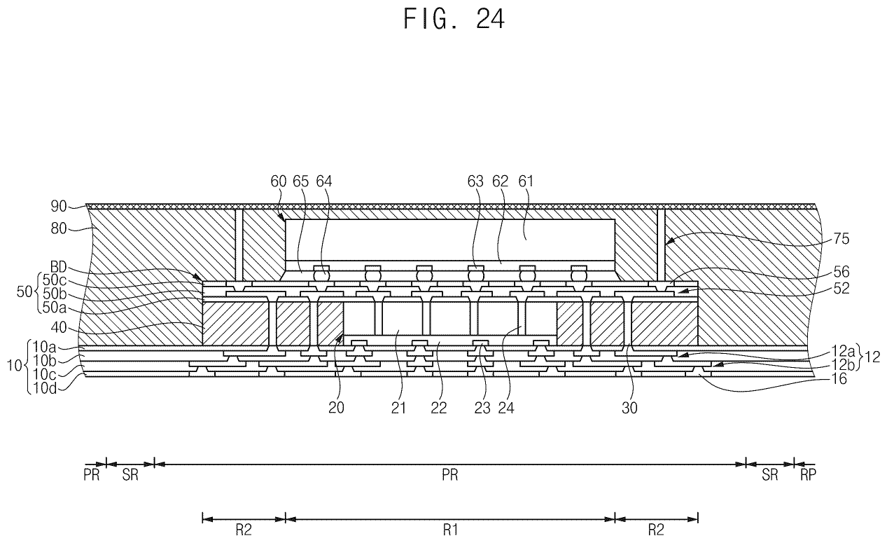

Referring to FIG. 24, processes the same as or similar to the processes described with reference to FIGS. 17 to 19 may be performed to form an upper sealing member 80 that covers the lower die structure BD, then upper semiconductor chip 60 and the conductive wires 70 on an upper surface of the second carrier substrate C2, and an electromagnetic shielding layer 90 may be formed on the upper sealing member 80.

Then, processes the same as or similar to the processes described with reference to FIG. 19 may be performed to form a lower redistribution wiring layer 10 having lower redistribution wirings 12 on a lower surface of the upper sealing member 80.

Then, conductive bumps may be formed on lower bonding pads 16 of the lower redistribution wiring layer 10, and the upper sealing member 80 may be cut along a scribe lane region SR to form a stack semiconductor chip 201 (see FIG. 1) as a chiplet package including the lower die structure BD having the first chiplet die 20 therein and the second chiplet die 20b stacked on the lower die structure BD.

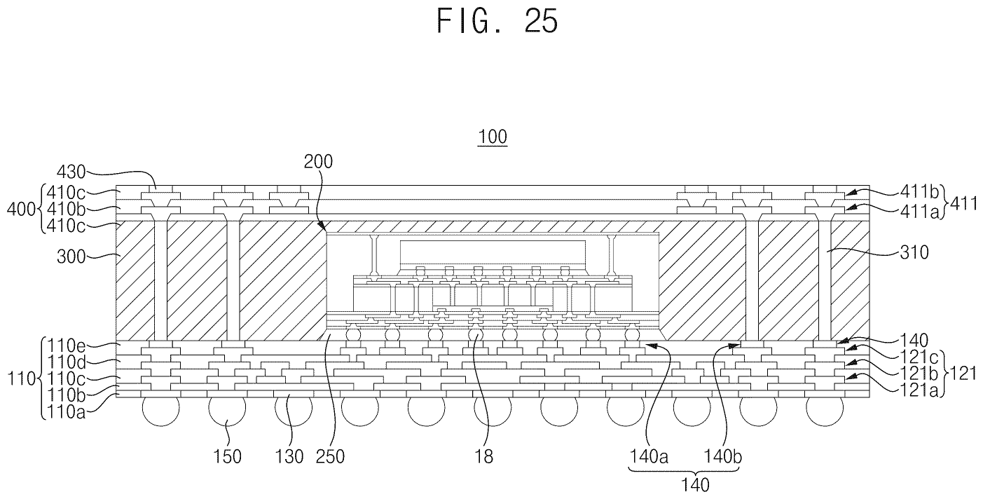

FIG. 25 is a cross-sectional view illustrating a semiconductor package in accordance with example embodiments. The semiconductor package includes the semiconductor packaging device illustrated in FIG. 1 or FIG. 20, however, the present inventive concept is not limited thereto.

Referring to FIG. 25, a semiconductor package 100 may include a lower redistribution wiring layer 110, a first semiconductor device 200 disposed on the lower redistribution wiring layer 110, a sealing member 300 on an upper surface of the lower redistribution wiring layer 110 and covering at least a portion of the first semiconductor device 200, and an upper redistribution wiring layer 400 disposed on an upper surface of the sealing member 300. Additionally, the semiconductor package 100 may further include external connection members 150 disposed on an outer surface of the lower redistribution wiring layer 110. The first semiconductor device 200 may be substantially the same as or similar to the semiconductor packaging device described with reference to FIG. 1 or FIG. 20. Thus, same reference numerals will be used to refer to the same or like elements and any further repetitive explanation concerning the above elements will be omitted.

In example embodiments, the semiconductor package 100 may be a fan-out package in which the lower redistribution wiring layer 110 extends to the sealing member 300 that covers an outer side surface of the first semiconductor device 200. The semiconductor package 100 may be a wafer-level fan-out package or a panel-level fan-out package.

Additionally, the semiconductor package 100 may be provided as a system in package (SIP). The semiconductor package 100 may be provided as a unit package on which a second package is stacked. In this case, the second package may include a second semiconductor device. For example, the first semiconductor device may include a logic chip including a logic circuit, and the second semiconductor device may include a memory chip. The logic chip may be a controller that controls the memory chip. The memory chip may include various types of memory circuits, such as DRAM, SRAM, flash, PRAM, ReRAM, FeRAM, or MRAM.

As illustrated in FIG. 25, the semiconductor package 100 may include the lower redistribution wiring layer 110, the first semiconductor device 200 mounted on the lower redistribution wiring layer 110, vertical conductive structures 310 disposed on the lower redistribution wiring layer 110 and electrically connected to the first semiconductor device 200, the sealing member 300 covering the first semiconductor device 200 on the lower redistribution wiring layer 110 and exposing upper end portions of the vertical conductive structures 310, and the upper redistribution wiring layer 400 on the sealing member 300 and electrically connected to the vertical conductive structures 310.

In example embodiments, the lower redistribution wiring layer 110 may be a front redistribution wiring layer (FRDL) of the fan-out package. The lower redistribution wiring layer 110 may include first to fifth lower insulating layers 110a, 110b, 110c, 110d, and 110e and circuit layers 120 having first redistribution wirings 121 in the lower insulating layers. The first redistribution wirings 121 may include first to third lower redistribution wirings 121a, 121b, and 121c that are vertically stacked.

Lower connection pads 130 may be exposed from (i.e., exposed at) a lower surface 114 of the lower redistribution wiring layer 110. Upper connection pads 140 may be exposed from (i.e., exposed at) an upper surface 112 of the lower redistribution wiring layer 110. The upper connection pads 140 may include first connection pads 140a disposed in a chip mounting region and second connection pads 140b disposed in a fan-out region surrounding the chip mounting region. The first connection pads 140a may be arranged in an array form within the chip mounting region on the upper surface 112. The lower connection pads 130 may be arranged in an array form over the entire lower surface 114. The upper connection pads 140 and the lower connection pads 130 may be electrically connected to each other through the first redistribution wirings. A data signal, a power signal, or a ground signal may be transmitted through the lower connection pads 130, the first redistribution wirings, and the upper connection pads 140.

The first semiconductor device 200 may be disposed in the chip mounting region, which is a fan-in region of the lower redistribution wiring layer 110. The first semiconductor device 200 may be mounted on the upper surface 112 of the lower redistribution wiring layer 110 using a flip chip bonding method. The first semiconductor device 200 may be electrically connected to the first redistribution wirings 121 of the lower redistribution wiring layer 110 through conductive bumps 18. The conductive bumps 18 may be respectively bonded to the first connection pads 140a on the uppermost first redistribution wiring 121c.

The vertical conductive pillars 310 as the vertical conductive structures may respectively extend upward on the second connection pads 140b located in the fan-out region of the lower redistribution wiring layer 110.

The sealing member 300 may cover the first semiconductor device 200 and the plurality of vertical conductive pillars 310 on the upper surface 112 of the lower redistribution wiring layer 110. The sealing member 300 may expose upper end portions of the vertical conductive pillars 310.

The upper redistribution wiring layer 400 may be disposed on the upper surface of the sealing member 300. The upper redistribution wiring layer 400 may include stacked first to third upper insulating layers 410a, 410b, and 410c and second redistribution wirings 411 in the first to third upper insulating layers 410a, 410b, and 410c. The second redistribution wirings 411 may include first and second upper redistribution wrings 411a and 411b. Upper connection pads 430 may be respectively disposed on the second upper redistribution wrings 411b as the uppermost redistribution wirings.

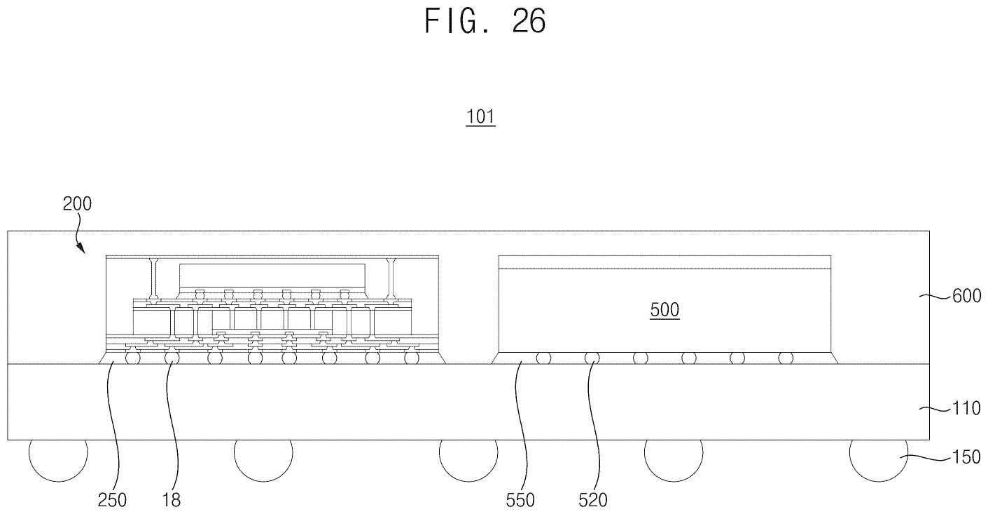

FIG. 26 is a cross-sectional view illustrating a semiconductor package in accordance with example embodiments. The semiconductor package includes the semiconductor packaging device illustrated in FIG. 1 or FIG. 20, however, the present inventive concept is not limited thereto.

Referring to FIG. 26, a semiconductor package 101 may include a package substrate 110, a first semiconductor device 200, and a second semiconductor device 500. Additionally, the semiconductor package 101 may further include first and second underfill members 250 and 550 and a sealing member 600. The first semiconductor device 200 may be substantially the same as or similar to the semiconductor package described with reference to FIG. 1 or FIG. 20. Thus, same reference numerals will be used to refer to the same or like elements and any further repetitive explanation concerning the above elements will be omitted.

In example embodiments, the semiconductor package 101 may be provided as a portion of a memory module with a 2.5D package structure. In this case, the package substrate 110 may be an interposer for electrically connecting the first and second semiconductor devices 200 and 500 to each other.

In example embodiments, the first semiconductor device 200 may include a logic device, and the second semiconductor device 500 may include a memory device. The logic device may be an application specific integrated circuit (ASIC) chip including, for example, a graphics processing unit (GPU), a central processing unit (CPU), a microprocessor, a microcontroller, an application processor (AP), a digital signal processing core (digital signal processing core), etc. The memory device may include, for example, DRAM, SRAM, flash, PRAM, ReRAM, FeRAM, or MRAM.

In example embodiments, the package substrate 110 may have an upper surface and a lower surface opposite to the upper surface, and may be, for example, a printed circuit board (PCB), a silicon interposer, or a redistribution interposer. The printed circuit board may be a multilayer circuit board having various circuit patterns therein.

The first semiconductor device 200 may be mounted on the package substrate 110. The first semiconductor device 200 may be mounted on an upper surface of the package substrate 110 using a flip chip bonding method. The first semiconductor device 200 may be electrically connected to substrate pads of the package substrate 110 through conductive bumps 18.

The second semiconductor device 500 may be horizontally spaced apart from the first semiconductor device 200 on the package substrate 110. The second semiconductor device 500 may be mounted on the upper surface of the package substrate 110 via conductive bumps 520.

The first semiconductor device 200 and the second semiconductor device 500 may be electrically connected to each other through wires inside the package substrate 110. The package substrate 110 may provide high-density interconnection between the first and second semiconductor devices 200 and 500.

In example embodiments, the first and second underfill members 250 and 550 may include a material with relatively high fluidity to effectively fill small spaces between the first and second semiconductor devices 200 and 500 and the package substrate 110. For example, the first and second underfill members 250 and 550 may include an adhesive containing an epoxy material.

The sealing member 600 may be provided on the upper surface of the package substrate 110 to cover the first and second semiconductor devices 200 and 500. For example, the sealing member 600 may include an epoxy mold compound (EMC). The sealing member 600 may include UV resin, polyurethane resin, silicone resin, silica fillers, etc.

Although not illustrated in the figure, a heat slug may cover and be in thermal contact with the first and second semiconductor devices 200 and 500 on the package substrate 110. In this case, the sealing member 600 may be omitted. Alternatively, the sealing member 600 may expose upper surfaces of the first and second semiconductor devices 200 and 500, and a heat dissipation member may be disposed on the upper surfaces of the first and second semiconductor devices 200 and 500 exposed by the sealing member 600, and the heat dissipation member may include, for example, a thermal interface material (TIM). The heat slug may be in thermal contact with the first and second semiconductor devices 200 and 500 via the heat dissipation member.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor packaging device, comprising:
a lower redistribution wiring layer;
a lower die structure stacked on the lower redistribution wiring layer, and comprising a first semiconductor chip, a lower sealing member extending around the first semiconductor chip, a plurality of through vias penetrating the lower sealing member, and an upper redistribution wiring layer on the lower sealing member, the upper redistribution wiring layer comprising first bonding pads in a first region and second bonding pads in a second region that extends around the first region;
a second semiconductor chip on the lower die structure in the first region;
an upper sealing member on the lower redistribution wiring layer and covering the lower die structure and the second semiconductor chip;
conductive ground structures extending from an upper surface of the upper sealing member to the second bonding pads in the second region of the upper redistribution wiring layer; and
an electromagnetic shielding layer on the upper surface of the upper sealing member and electrically connected to the conductive ground structures.

2. The semiconductor packaging device of claim 1, wherein the first semiconductor chip comprises a first substrate, a first front insulating layer on a first surface of the first substrate, the first front insulating layer comprising first chip pads, and a plurality of through electrodes penetrating the first substrate and electrically connected to the first chip pads.

3. The semiconductor packaging device of claim 2, wherein the upper redistribution wiring layer comprises upper redistribution wirings that are electrically connected to the first chip pads and the plurality of through vias.

4. The semiconductor packaging device of claim 2, wherein the lower redistribution wiring layer comprises lower redistribution wirings that are electrically connected to the first chip pads and the plurality of through vias.

5. The semiconductor packaging device of claim 1, wherein the second semiconductor chip comprises a front surface on which second chip pads are formed, and wherein the second semiconductor chip is arranged such that the front surface faces the upper redistribution wiring layer.

6. The semiconductor packaging device of claim 5, wherein the second semiconductor chip is mounted on the upper redistribution wiring layer by conductive bumps, and wherein each of the conductive bumps is between a respective one of the first bonding pads and a respective one of the second chip pads.

7. The semiconductor packaging device of claim 1, wherein the conductive ground structures comprise conductive wires, and
wherein each of the conductive wires comprises:
a wire body extending in a first direction;
a first bonding end portion at a first end portion of the wire body and bonded to a respective one of the second bonding pads; and
a second bonding end portion at a second end portion of the wire body and exposed at the upper surface of the upper sealing member.

8. The semiconductor packaging device of claim 1, wherein each of the conductive ground structures comprises a conductive pillar that extends from a respective one of the second bonding pads to the upper surface of the upper sealing member.

9. The semiconductor packaging device of claim 1, wherein the lower sealing member has a first elastic modulus, and the upper sealing member has a second elastic modulus that is less than the first elastic modulus.

10. The semiconductor packaging device of claim 1, wherein the first semiconductor chip has a first size and the second semiconductor chip has a second size greater than the first size.

11. A semiconductor packaging device, comprising:
a lower redistribution wiring layer;
a lower sealing member on the lower redistribution wiring layer, wherein the lower sealing member contains a first chiplet die and comprises a plurality of through vias therein;
an upper redistribution wiring layer on the lower sealing member and comprising first bonding pads in a first region of the upper redistribution wiring layer and second bonding pads in a second region of the upper redistribution wiring layer that extends peripherally around the first region of the upper redistribution wiring layer;
a second chiplet die in the first region of the upper redistribution wiring layer;
an upper sealing member on the lower redistribution wiring layer and covering the lower sealing member, the upper redistribution wiring layer, and the second chiplet die;
a plurality of conductive ground structures extending from an upper surface of the upper sealing member to the second bonding pads of the upper redistribution wiring layer; and
an electromagnetic shielding layer on the upper surface of the upper sealing member and electrically connected to the conductive ground structures.

12. The semiconductor packaging device of claim 11, wherein the first chiplet die comprises a first substrate, a first front insulating layer on a first surface of the first substrate, first chip pads on the first surface of the first substrate, and a plurality of through electrodes penetrating through the first substrate and electrically connected to the first chip pads.

13. The semiconductor packaging device of claim 12, wherein the upper redistribution wiring layer comprises upper redistribution wirings that are electrically connected to the first chip pads and the plurality of through vias.

14. The semiconductor packaging device of claim 12, wherein the lower redistribution wiring layer comprises lower redistribution wirings that are electrically connected to the first chip pads and the plurality of through vias.

15. The semiconductor packaging device of claim 11, wherein the second chiplet die comprises a front surface on which second chip pads are formed, and wherein the second chiplet die is arranged such that the front surface faces the upper redistribution wiring layer.

16. The semiconductor packaging device of claim 15, wherein the second chiplet die is mounted on the upper redistribution wiring layer by conductive bumps, and wherein each of the conductive bumps is between a respective one of the first bonding pads and a respective one of the second chip pads.

17. The semiconductor packaging device of claim 11, wherein the conductive ground structures comprises conductive wires, and
wherein each of the conductive wires comprises:
a wire body extending in a first direction;
a first bonding end portion at a first end portion of the wire body and bonded to the second bonding pad; and
a second bonding end portion at a second end portion of the wire body and exposed at the upper surface of the upper sealing member.

18. The semiconductor packaging device of claim 11, wherein each of the conductive ground structures comprises a conductive pillar that extends from a respective one of the second bonding pads to the upper surface of the upper sealing member.

19. The semiconductor packaging device of claim 11, wherein the lower sealing member has a first elastic modulus, and the upper sealing member has a second elastic modulus that is less than the first elastic modulus.

20. A semiconductor packaging device, comprising:
a lower redistribution wiring layer;
a first chiplet die on the lower redistribution wiring layer and having a first size;
a lower sealing member extending around the first chiplet die and comprising a plurality of through vias therein;
an upper redistribution wiring layer on the first chiplet die and the lower sealing member, and comprising first bonding pads in a first region of the upper redistribution wiring layer and second bonding pads in a second region of the upper redistribution wiring layer that extends peripherally around the first region of the upper redistribution wiring layer;
a second chiplet die in the first region of the upper redistribution wiring layer and having a second size greater than the first size;
an upper sealing member on the lower redistribution wiring layer and covering the lower sealing member, the upper redistribution wiring layer and the second chiplet die;
a plurality of conductive ground structures extending from an upper surface of the upper sealing member to the second bonding pads in the second region of the upper redistribution wiring layer; and
an electromagnetic shielding layer on an upper surface of the upper sealing member and electrically connected to the conductive ground structures.
